(19) United States
(12) Patent Application Publication
(10) Pub. No.: US 2017/0110353 A1
(43) Pub. Date: Apr. 20, 2017

(54) WAFER BOAT, ANNEALING TOOL AND ANNEALING METHOD

(71) Applicant: TAIWAN SEMICONDUCTOR MANUFACTURING CO., LTD., Hsinchu (TW)

(72) Inventors: Ho-Cheng CHAO, Hsinchu City (TW); Shun-Chin CHEN, Hsinchu County (TW); Shao-Hua WANG, Hsinchu City (TW); Shih-Fang CHEN, Hsinchu County (TW)

(21) Appl. No.: 14/918,071

(22) Filed: Oct. 20, 2015

(51) Int. Cl. H01L 21/673; H01L 21/324; H01L 21/67

(52) U.S. Cl. CPC H01L 21/67309; H01L 21/67109; H01L 21/324

(57) ABSTRACT

A wafer boat includes a base, a plurality of support rods and a plurality of cantilever arms. The support rods are carried by the base. The support rods are disposed around a space above the base. The cantilever arms are carried by the support rods. At least two of the cantilever arms carried by at least one of the support rods are vertically spaced apart to define at least one slot for a wafer.

### BACKGROUND

The present disclosure generally relates to wafer boats, and specifically relates to wafer boats of annealing tools.

Thermal annealing is one of the manufacturing processes in the industry of semiconductor production nowadays. During the process of thermal annealing, wafers are held in a space and are thermally treated with a high temperature. When the wafers are heated up during the process of thermal annealing, the temperature of the wafers increases and the thermal expansion of the wafers occurs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a wafer boat in accordance with some embodiments of the present disclosure.

FIG. 2 is a sectional view of the wafer boat of FIG. 1 present in an annealing tool.

FIG. 3 is an enlarged view of part A in FIG. 2, with the wafer placed in the slot.

FIG. 4 is a sectional view along the section line B-B of FIG. 2.

FIG. 5 is a sectional view along the section line B-B of FIG. 2, in which a wafer is delivered to the space by a tool.

FIG. 6 is a sectional view along the section line B-B of FIG. 2, in which the wafer is supported by the cantilever arms.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, operations, operations, elements, and/or components, but do not preclude the presence or addition of one or more other features, regions, integers, operations, operations, elements, components, and/or groups thereof.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

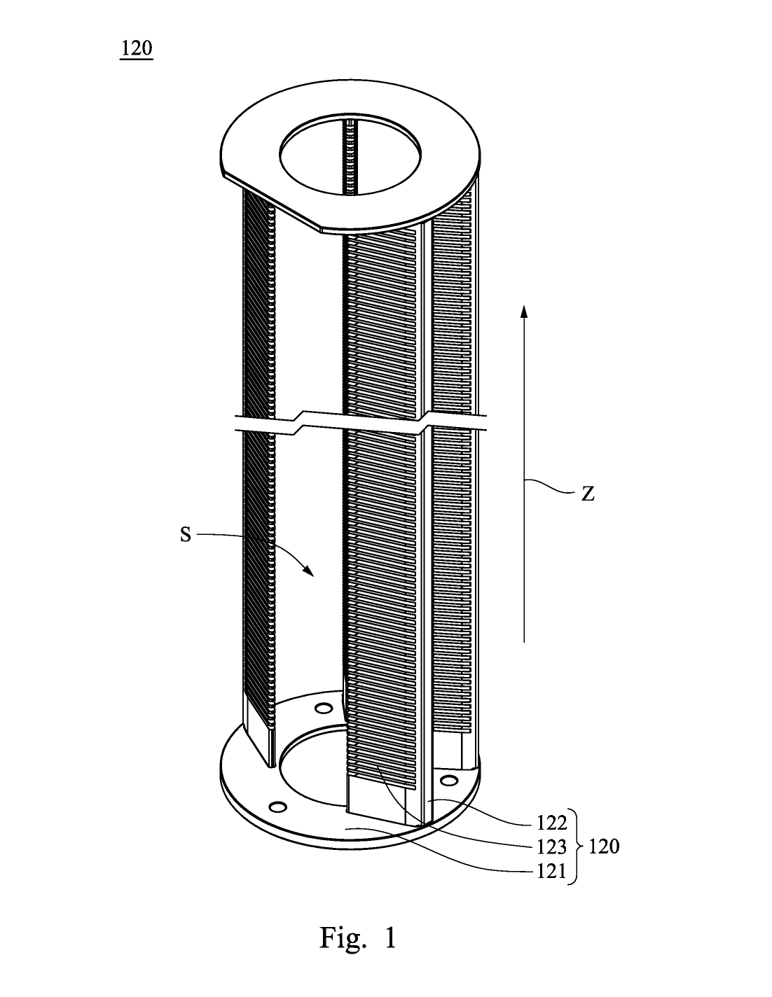

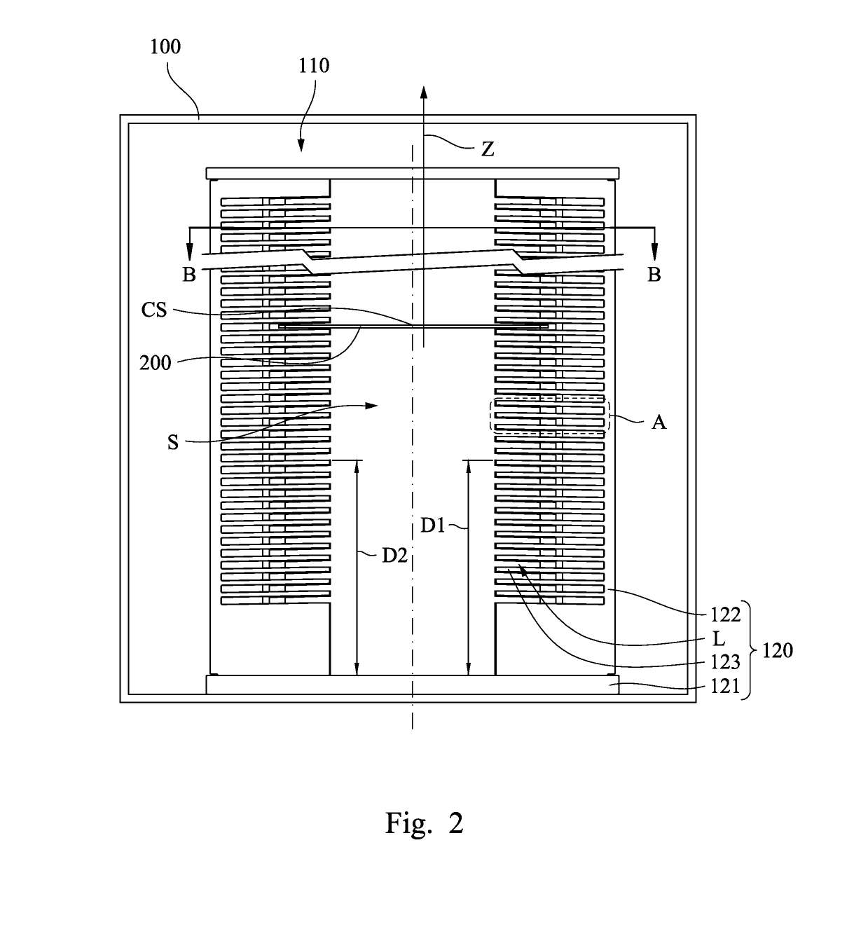

Reference is made to FIGS. 1-2. FIG. 1 is a schematic view of a wafer boat 120 in accordance with some embodiments of the present disclosure. FIG. 2 is a sectional view of the wafer boat 120 of FIG. 1 present in an annealing tool 100. In some embodiments, as shown in FIGS. 1-2, the annealing tool 100 includes an annealing chamber 110 and a wafer boat 120. The wafer boat 120 is present in the annealing chamber 110. The wafer boat 120 includes at least one support rod 122 and at least one cantilever arm 123. The cantilever arm 123 is stationary with respect to the support rod 122 and is configured to support a wafer 200 (shown in FIG. 2).

To be more specific, in some embodiments, the wafer boat 120 includes a base 121, a plurality of support rods 122 and a plurality of cantilever arms 123. The support rods 122 are carried by the base 121. The support rods 122 are disposed around a space S above the base 121. The cantilever arms 123 are carried by the support rods 122. At least two of the cantilever arms 123 are vertically spaced apart to define at least one slot L (shown in FIG. 2) for the wafer 200. In this way, the wafer 200 can be placed in the space S above the base 121 of the annealing tool 100 and is supported at the slot L by the cantilever arms 123 of the wafer boat 120. In practical applications, at least one of the support rods 122 is detachably coupled with the base 121.

Since the wafer 200 is supported by the cantilever arms 123 of the wafer boat 120, the position of the supports to the wafer 200 by the cantilever arms 123 of the wafer boat 120 depends on the length of the cantilever arms 123. Therefore, the position of the supports to the wafer 200 by the cantilever arms 123 can lie between a center CS of the wafer 200 and an edge of the wafer 200. In this way, during the operation of the annealing tool 100, when the temperature of the wafer 200 rises up, the degree of deformation of the wafer 200 near the center CS due to the thermal expansion of the wafer 200 is reduced. As a result, during the operation of the annealing tool 100, the chance of failure of wafer overlay due to the deformation of the wafer 200 near the center CS because of the thermal expansion is reduced. For instance, the position of the supports to the wafer 200 by the cantilever arms 123 of the wafer boat 120 can be approximately at the middle region between the center CS and the edge of the wafer 200.

In some embodiments, at least one of the cantilever arms 123 is made of silicon. In practical applications, the wafer 200 is mainly made of silicon. Therefore, the cantilever arms 123 and the wafer 200 have a similar coefficient of thermal expansion. In this way, during the operation of the annealing tool 100, when the temperature of both the cantilever arms 123 and the wafer 200 rises up, the magnitude that the cantilever arms 123 and the wafer 200 expand thermally will be of substantially the same order. Thus, the friction generated between the cantilever arms 123 and the wafer 200 due to different coefficients of thermal expansion of the cantilever arms 123 and the wafer 200 is avoided. As a result, particles from either the cantilever arms 123 or the wafer 200 unexpectedly produced due to the friction generated between the cantilever arms 123 and the wafer 200 are reduced. Consequently, during the operation of the annealing tool 100, the contamination to the wafer 200 by the unexpected particles from either the cantilever arms 123 or the wafer 200 is avoided. Thus, the chance for the defect of wafer 200 is correspondingly reduced.

In some embodiments, at least one of the cantilever arms 123 and at least one of the support rods 122 carrying said one of the cantilever arms 123 are made of the same material. In other words, the cantilever arm 123 has a coefficient of thermal expansion substantially the same as that of the support rod 122. In this way, during the operation of the annealing tool 100, when the temperature of both the support rod 122 and the corresponding cantilever arms 123 rises up, the magnitude that the support rod 122 and the cantilever arms 123 expand thermally will be of the same order. Thus, the friction generated between the support rod 122 and the corresponding cantilever arms 123 due to different coefficients of thermal expansion of the support rod 122 and the corresponding cantilever arms 123 is reduced. As a result, particles from either the support rod 122 or the corresponding cantilever arms 123 unexpectedly produced due to the friction generated between the support rod 122 or the corresponding cantilever arms 123 is reduced. Consequently, during the operation of the annealing tool 100, the contamination to the wafer 200 by the unexpected particles from either the support rod 122 or the corresponding cantilever arms 123 is avoided. Thus, the chance for the defect of wafer 200 is correspondingly reduced.

As mentioned above, the cantilever arms 123 are carried by the support rods 122. In some embodiments, at least one of the cantilever arms 123 and at least one of the support rods 122 carrying said one of the cantilever arms 123 are monolithically formed. In other words, the cantilever arm 123 and the corresponding support rod 122 are integrally formed. Therefore, the support rod 122 and the corresponding cantilever arms 123 will have the same coefficient of thermal expansion.

In addition, since the cantilever arm 123 and the corresponding support rod 122 are integrally formed as mentioned above, the relative movement between the support rod 122 and the corresponding cantilever arm 123 is avoided. Thus, the attachment of the cantilever arms 123 to and the detachment of the cantilever arms 123 from the corresponding support rod 122 during or after the operation of the annealing tool 100 are also avoided. Therefore, the adjustment of the cantilever arms 123 relative to the support rods 122 is also avoided. As a result, the efficiency for the operation of the annealing tool 100 is increased while the cost of operation is correspondingly decreased.

At mentioned above, at least two of the cantilever arms 123 are vertically spaced apart to define at least one slot L for the wafer 200. As shown in FIGS. 1-2, the cantilever arms 123 carried by each of the support rod 122 are arranged substantially in equal intervals along the direction Z. Within each interval between two adjacent cantilever arms 123, one slot L is defined and a piece of the wafer 200 is placed and supported. In some embodiments, the quantity of the cantilever arms 123 carried by each of the support rod 122 can be in a range from about 100 to about 180. This means, the annealing tool 100 can support a quantity of about 100 to about 180 pieces of the wafers 200 by the cantilever arms 123 of the wafer boat 120 at the same time.

In order to achieve a stable support to the wafer 200, at least two of the cantilever arms 123 are horizontally aligned. In other words, a distance of each of the cantilever arms 123 carried by any one of the support rod 122 from the base 121 is substantially the same as a distance of the corresponding cantilever arm 123 carried by the other support rod 122 from the base 121. For instance, as shown in FIG. 2, a distance D1 of one of the cantilever arms 123 carried by the support rod 122 on the right hand side on the page is the same as a distance D2 of the corresponding cantilever arm 123 carried by the support rod 122 on the left hand side. In this way, the wafer 200 can be supported horizontally in the annealing tool 100 by the cantilever arms 123 of the wafer boat 120 in a stable manner.

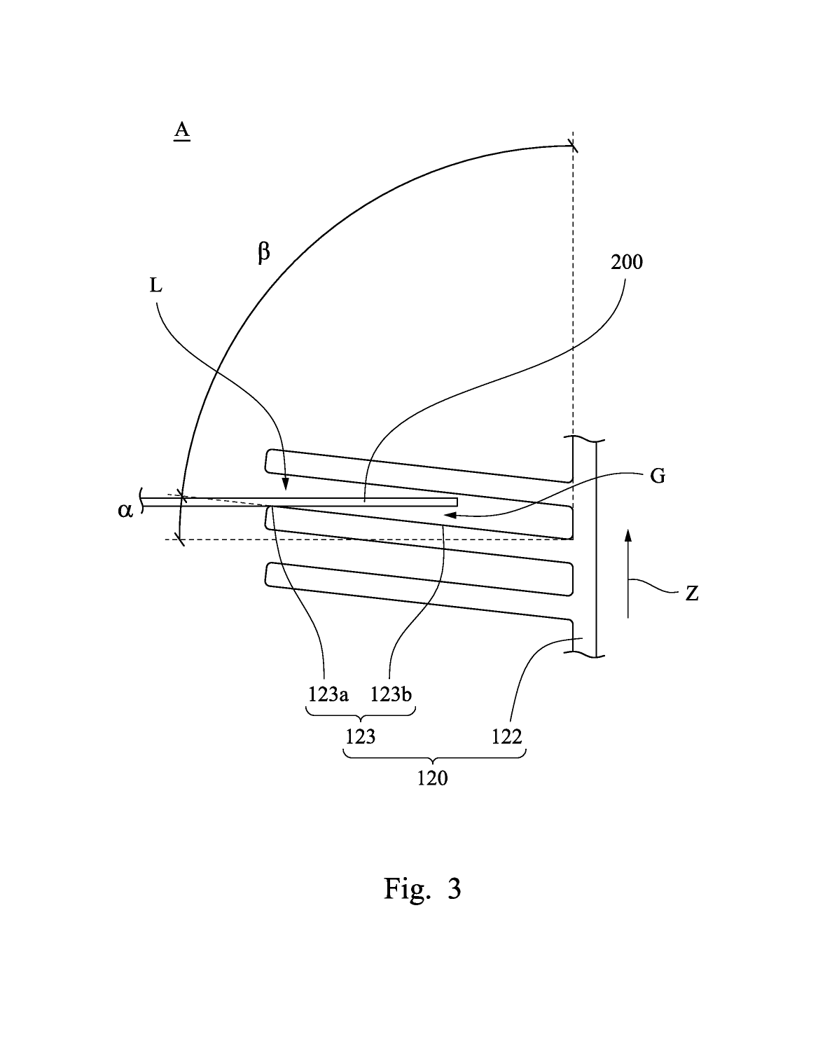

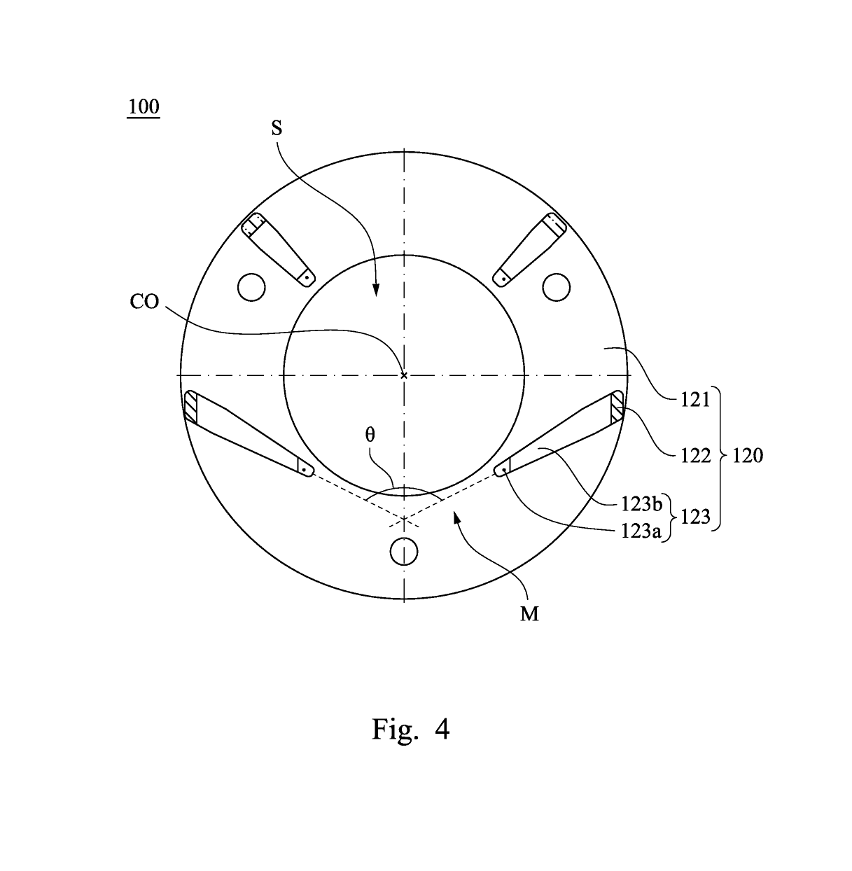

Reference is made to FIGS. 3-4. FIG. 3 is an enlarged view of part A in FIG. 2, with the wafer 200 placed in the slot L. FIG. 4 is a sectional view along the section line B-B of FIG. 2. As shown in FIGS. 2-4, in some embodiments, at least one of the cantilever arms 123 has a contact area 123a and a non-contact area 123b. The contact area 123a is configured to be in contact with the wafer 200 to support the wafer 200 in the space S above the base 121. The non-contact area 123b is configured to be free from contact with the wafer 200 to leave a gap G between the wafer 200 and the non-contact area 123b when the wafer 200 is supported by the contact area 123a. To be more specific, each of the cantilever arms 123 has proximal and distal halves respective proximal and distal to at least one of the support rods 122 carrying said one of the cantilever arms 123, and the contact area 123a is present on the distal half. In other words, the non-contact area 123b is present between the contact area 123a and the support rod 122. In this way, the area of contact, i.e., the contact area 123a, that each of the cantilever arms 123 contacts and supports the wafer 200 is reduced. In this way, the effect to the wafer 200 due to the thermal expansion of each of the cantilever arms 123 and the wafer 200 during the operation of the annealing tool 100 is further reduced. Furthermore, in practical applications, the contact area 123a of each of the cantilever arms 123 is treated such that the contact areas 123a has a relatively low degree of roughness. In this way, when the contact areas 123a of the cantilever arms 123 contact and support the wafer 200, the contact areas 123a will not wear and damage the surface of the wafer 200.

In addition, as shown in FIG. 3, at least one of the cantilever arms 123 tilts toward the slot L. In other words, each of the cantilever arms 123 tilts towards the wafer 200. In some embodiments, the cantilever arms 131 tilts by an angle a towards the wafer 200. In some embodiments, the angle a ranges from 0 degree to 5 degree. In contrast, an angle β between each of the cantilever arms 123 and the corresponding support rod 122 ranges from 85 degree to 90 degree towards the direction Z along the corresponding support rod 122, in which the sum of the angle a and the angle β is 90 degree. In this way, when the wafer 200 is supported by the cantilever arms 123, the contact area 123a present on the distal half away from the support rod 122 contacts and supports the wafer 200 in the space S. Therefore, the area of contact, i.e., the contact area 123a, that each of the cantilever arms 123 contacts and supports the wafer 200 is reduced. In this way, the effect to the wafer 200 due to the thermal expansion of each of the cantilever arms 123 and the wafer 200 during the operation of the annealing tool 100 is further reduced.

As shown in FIGS. 1-2 and 4, in some embodiments, the quantity of the support rods 130 is 4. On the other hand, in some other embodiments, the quantity of the support rods 130 can be in a range from about 3 to about 6. As shown in FIG. 4, a centroid CO of the contact areas 123a of the four cantilever arms 123 is marked and the centroid CO is located in the space S above the base 121. Geometrically speaking, the centroid CO is the arithmetic mean position of the contact areas 123a of the four corresponding cantilever arms 123.

In addition, in order to place the wafer 200 to the space S above the base 121 and support the wafer 200 by the cantilever arms 123 of the wafer boat 120, at least two of the cantilever arms 123 are horizontally spaced apart. In some embodiments, at least two of the cantilever arms 123 form an opening M in between such that the opening M allows a tool (not shown in FIG. 4) for delivering the wafer 200 to the space S to pass through. As shown in FIG. 4, the lower left cantilever arm 123 and the lower right cantilever arm 123 on the page form an opening M in between. Therefore, the tool can pass through the opening M without touching the cantilever arms 123 of the wafer boat 120 and the tool can deliver the wafer 200 into the space S from the lower side of the page.

To be more specific, the two support rods 122 carrying the corresponding cantilever arms 123 forming the opening M are orientated such that the extensions of the corresponding cantilever arms 123 form an angle 0, in which the angle 0 is away from the centroid CO of the contact areas 123a of the four corresponding cantilever arms 123. In this way, the lower left cantilever arm 123 and the lower right cantilever arm 123 on the page of FIG. 4 are disposed leaving a the route of the tool entering into or moving away from the space S above the base 121 through the opening M. In other words, the support rod 122 do not hinder the wafer 200 or the tool when the tool and the wafer 200 enter into the space S, or when the tool moves away from the space S. This means, the tool will not touch the cantilever arms 123 of the wafer boat 120 when passing through the opening M.

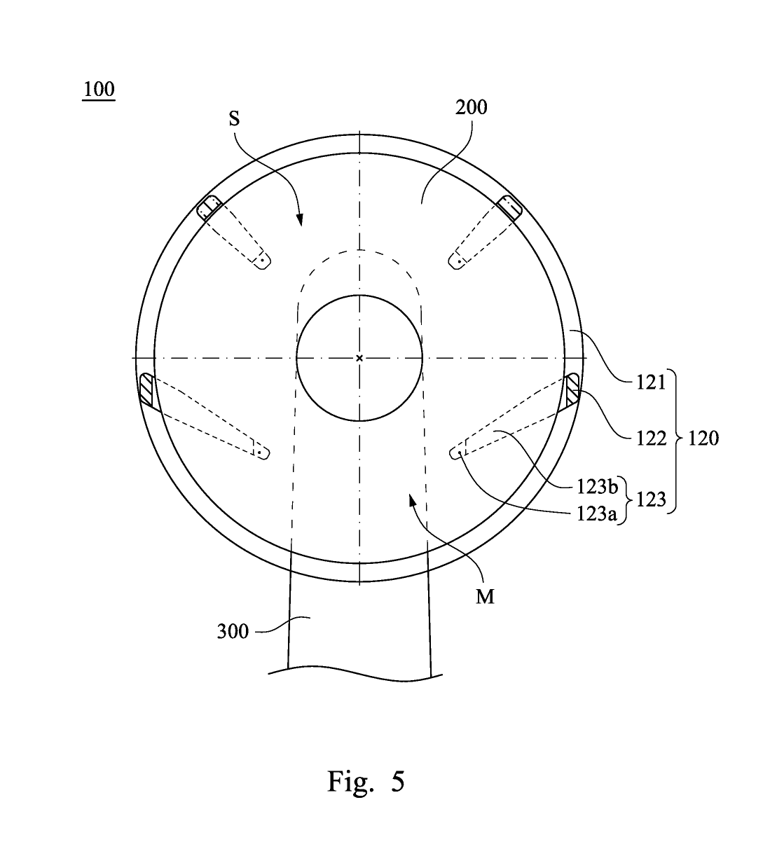

Reference is made to FIG. 5. FIG. 5 is a sectional view along the section line B-B of FIG. 2, in which the wafer 200 is delivered to the space S by a tool 300. As shown in FIG. 5, the tool 300 holds the wafer 200 and enters into the space S above the base 121 through the opening M. The opening M is formed between the two the cantilever arms 123. After the wafer 200 is contacted and supported by the contact areas 123a of the cantilever arms 123, the tool 300 is removed from the space S through the opening M with the wafer 200 staying in the space S as contacted and supported by the contact areas 123a of the cantilever arms 123.

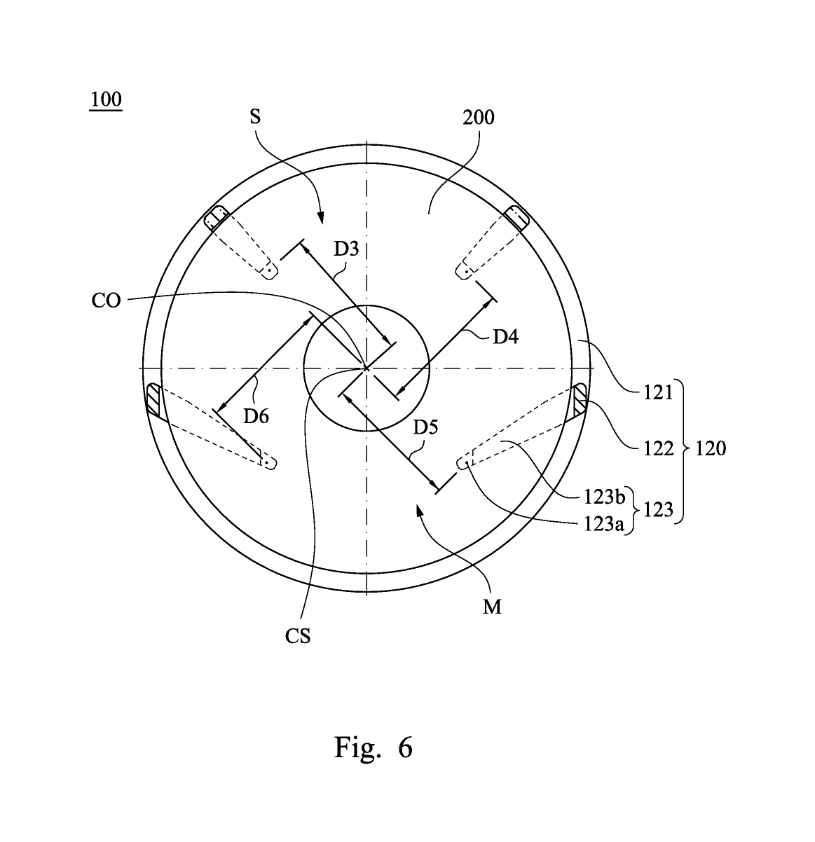

Reference is made to FIG. 6. FIG. 6 is a sectional view along the section line B-B of FIG. 2, in which the wafer 200 is supported by the cantilever arms 123. As shown in FIG. 6, the wafer 200 is located in the space S above the base 121. For the sake of geometrical stability, the centroid CO of the contact areas 123a of the cantilever arms 123 is close to the center CS of the wafer 200. In some embodiments, as shown in FIG. 6, the centroid CO of the contact areas 123a of the cantilever arms 123 coincides with the center CS of the wafer 200. However, in practical applications, a tolerance between the centroid CO of the contact areas 123a of the cantilever arms 123 and the center CS of the wafer 200 is allowed. In other words, a distance is allowed between the centroid CO of the contact areas 123a of the cantilever arms 123 and the center CS of the wafer 200.

In addition, for the sake of geometrical stability, distances between the contact areas 123a of each of the cantilever arms 123 and the center CS of the wafer 200 are substantially the same. For instance, as shown in FIG. 6, the distance D3 between the contact area 123a of the cantilever arms 123 at the upper left of the page and the center CS of the wafer 200, the distance D4 between the contact area 123a of the cantilever arms 123 at the upper right of the page and the center CS of the wafer 200, the distance D5 between the contact area 123a of the cantilever arms 123 at the lower right of the page and the center CS of the wafer 200, and the distance D6 between the contact area 123a of the cantilever arms 123 at the lower left of the page and the center CS of the wafer 200 are substantially the same. In this way, the contact areas 123a of the cantilever arms 123 can contact and support the wafer 200 in a stable manner. In some embodiments, the distances D3, D4, D5 and D6 respectively between the contact areas 123a of the cantilever arms 123 and the center CS of the wafer 200 are set such that the position of the supports to the wafer 200 by the cantilever arms 123 are located approximately at the middle region between the center CS and the edge of the wafer 200.

With reference to the annealing tool 100 as mentioned above, the embodiments of the present disclosure further provide an annealing method. The method includes the following steps (it is appreciated that the sequence of the steps and the sub-steps as mentioned below, unless otherwise specified, all can be adjusted according to the actual needs, or even executed at the same time or partially at the same time):

(1) moving at least one wafer 200 to the wafer boat 120.

(2) supporting the wafer 200 by at least one cantilever arm 123 of the wafer boat 120.

(3) annealing the wafer 200 supported by the cantilever arm 123 of the wafer boat 120.

In details, during the application of the annealing method to at least one wafer 200, the wafer 200 is moved to the wafer boat 120. Afterwards, the wafer 200 is supported by at least one cantilever arm 123 of the wafer boat 120. Consequently, the wafer 200 supported by the cantilever arm 123 of the wafer boat 120 is annealed.

To be more specific, since the wafer 200 is supported by at least one cantilever arm 123 of the wafer boat 120, the position of the supports to the wafer 200 by the cantilever arm 123 of the wafer boat 120 depends on the length of the cantilever arm 123. Therefore, the position of the support to the wafer 200 by the cantilever arm 123 can lie between a center CS of the wafer 200 and the edge of the wafer 200. In this way, during the operation of the annealing tool 100, when the temperature of the wafer 200 rises up, the degree of deformation of the wafer 200 near the center CS due to the thermal expansion of the wafer 200 is reduced. As a result, during the operation of the annealing tool 100, the chance of failure of wafer overlay due to the deformation of the wafer 200 near the center CS because of the thermal expansion is reduced. For instance, the position of the support to the wafer 200 by the cantilever arm 123 of the wafer boat 120 can be approximately at the middle region between the center CS and the edge of the wafer 200.

In order to reduce the area of contact, i.e., the contact area 123a, that each of the cantilever arms 123 contacts and supports the wafer 200, the step of supporting the wafer 200 (step 2) further includes:

(2.1) supporting the wafer 200 by the contact area 123a of the cantilever arm 123 while leaving a space, i.e., the gap G, between the wafer 200 and the non-contact area 123b of the cantilever arm 123.

With the gap G left between the wafer 200 and the non-contact area 123b of the cantilever arm 123, the effect to the wafer 200 due to the thermal expansion of each of the cantilever arms 123 and the wafer 200 during the operation of the annealing tool 100 is further reduced.

In some embodiments, the cantilever arm 123 of the wafer boat 120 has a coefficient of thermal expansion substantially the same as that of the wafer 200. In this way, during the operation of the annealing tool 100, when the temperature of both the cantilever arms 123 and the wafer 200 rises up, the magnitude that the cantilever arms 123 and the wafer 200 expand thermally will be of substantially the same order. Thus, the friction generated between the cantilever arms 123 and the wafer 200 due to different coefficients of thermal expansion of the cantilever arms 123 and the wafer 200 is avoided. As a result, particles from either the cantilever arms 123 or the wafer 200 unexpectedly produced due to the friction generated between the cantilever arms 123 and the wafer 200 are reduced. Consequently, during the operation of the annealing tool 100, the contamination to the wafer 200 by the unexpected particles from either the cantilever arms 123 or the wafer 200 is avoided. Thus, the chance for the defect of wafer 200 is correspondingly reduced.

According to various embodiments of the present disclosure, since the wafer 200 is supported by the cantilever arms 123 of the wafer boat 120, the position of the supports to the wafer 200 by the cantilever arms 123 of the wafer boat 120 depends on the length of the cantilever arms 123. Therefore, the position of the supports to the wafer 200 by the cantilever arms 123 can lie between a center CS of the wafer 200 and the edge of the wafer 200. In this way, during the operation of the annealing tool 100, when the temperature of the wafer 200 rises up, the degree of deformation of the wafer 200 near the center CS due to the thermal expansion of the wafer 200 is reduced. As a result, during the operation of the annealing tool 100, the chance of failure of wafer overlay due to the deformation of the wafer 200 near the center CS because of the thermal expansion is reduced. For instance, the position of the supports to the wafer 200 by the cantilever arms 123 of the wafer boat 120 can be approximately at the middle region between the center CS and the edge of the wafer 200.

According to various embodiments of the present disclosure, the wafer boat includes the base, a plurality of support rods and a plurality of cantilever arms. The support rods are carried by the base. The support rods are disposed around the space above the space. The cantilever arms are carried by the support rods. At least two of the cantilever arms carried by at least one of the support rods are vertically spaced apart to define at least one slot for the wafer.

According to various embodiments of the present disclosure, the annealing tool includes the annealing chamber and the wafer boat. The wafer boat is present in the annealing chamber. The wafer boat includes at least one support rod and at least one cantilever arm. The cantilever arm is stationary with respect to the support rod and is configured to support the wafer.

According to various embodiments of the present disclosure, the annealing method includes moving at least one wafer to the wafer boat, supporting the wafer by at least one cantilever arm of the wafer boat, and annealing the wafer supported by the cantilever arm of the wafer boat.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A wafer boat, comprising:
a base;
a plurality of support rods carried by the base, the support rods being disposed around a space above the base; and
a plurality of cantilever arms carried by the support rods, wherein at least two of the cantilever arms carried by at least one of the support rods are vertically spaced apart to define at least one slot for a wafer.

2. The wafer boat of claim 1, wherein at least one of the cantilever arms and at least one of the support rods carrying said one of the cantilever arms are made of the same material.

3. The wafer boat of claim 1, wherein at least one of the cantilever arms is made of silicon.

4. The wafer boat of claim 1, wherein at least one of the cantilever arms and at least one of the support rods carrying said one of the cantilever arms are monolithically formed.

5. The wafer boat of claim 1, wherein at least two of the cantilever arms are horizontally aligned.

6. The wafer boat of claim 5, wherein said two of the cantilever arms are horizontally spaced apart.

7. The wafer boat of claim 1, wherein at least one of the cantilever arms tilts toward the slot.

8. The wafer boat of claim 1, wherein at least one of the cantilever arms has a contact area configured to support the wafer and a non-contact area configured to leave a gap between the wafer and the non-contact area when the wafer is supported by the contact area.

9. The wafer boat of claim 8, wherein said one of the cantilever arms has proximal and distal halves respective proximal and distal to at least one of the support rods carrying said one of the cantilever arms, and the contact area is present on the distal half.

10. The wafer boat of claim 1, wherein at least one of the support rods is detachably coupled with the base.

11. An annealing tool, comprising:
an annealing chamber; and
a wafer boat present in the annealing chamber, the wafer boat comprising:
at least one support rod; and
at least one cantilever arm stationary with respect to the support rod and configured to support a wafer.

12. The annealing tool of claim 11, wherein the cantilever arm has a coefficient of thermal expansion substantially the same as that of the support rod.

13. The annealing tool of claim 11, wherein the cantilever arm and the support rod are integrally formed.

14. The annealing tool of claim 11, wherein the cantilever arm tilts toward the wafer.

15. The annealing tool of claim 11, wherein the cantilever arm has a contact area configured to be in contact with the wafer and a non-contact area configured to be free from contact with the wafer.

16. The annealing tool of claim 15, wherein the non-contact area is present between the contact area and the support rod.

17. The annealing tool of claim 11, further comprising:
a base, the support rod being detachably coupled with the base.

18. An annealing method, comprising:
moving at least one wafer to a wafer boat;
supporting the wafer by at least one cantilever arm of the wafer boat; and
annealing the wafer supported by the cantilever arm of the wafer boat.

19. The annealing method of claim 18, wherein the supporting the wafer comprises:
supporting the wafer by a contact area of the cantilever arm while leaving a space between the wafer and a non-contact area of the cantilever arm.

20. The annealing method of claim 18, wherein the cantilever arm of the wafer boat has a coefficient of thermal expansion substantially the same as that of the wafer.
